(19) United States
(12) Patent Application Publication
(10) Pub. No.: US 2021/0171801 A1
(43) Pub. Date: Jun. 10, 2021

(54) POLISHING COMPOSITION

(71) Applicant: NITTA DuPont Incorporated, Osaka (JP)

(72) Inventor: Shuhei MATSUDA, Kyotanabe-shi, Kyoto (JP)

(21) Appl. No.: 17/253,616

(22) PCT Filed: Aug. 1, 2019
(86) PCT No.: PCT/JP2019/030215

§ 371 Date: Dec. 18, 2020

(30) Foreign Application Priority Data
Aug. 3, 2018 (JP) 2018-146643

(51) Int. Cl. C09G 1/02; C09G 1/18; C09G 1/16

(52) U.S. Cl. CPC C09G 1/02; C09G 1/16; C09G 1/18

(57) ABSTRACT

A polishing composition is provided that is capable of quickly removing oxide film even with lower abrasive concentration. A polishing composition includes: silica with a silanol group density of 2.0 OH/nm² or higher; and an organic silicon compound having, at a terminal, an amino group, methylamino group, dimethylamino group or quaternary ammonium group, the organic silicon compound having two or more alkoxyl groups or hydroxyl groups bonded to an Si atom thereof. However, the quaternary ammonium group of the organic silicon compound does not have an alkyl group with a carbon number of two or more.

### RELATED APPLICATIONS

The present application is a National Phase of International Application Number PCT/JP2019/030215, filed Aug. 1, 2019, which claims priority to Japanese Application No. 2018-146643, filed Aug. 3, 2018.

### TECHNICAL FIELD

The present invention relates to a polishing composition.

### BACKGROUND ART

Polishing compositions used to polish silicon wafers contain abrasives and basic compounds. For example, Japanese Patent No. 3937143 discloses a silicon wafer polishing composition including silica serving as polishing abrasives and containing organosilane having amino groups or a partial hydrolysis condensate thereof.

### DISCLOSURE OF THE INVENTION

To polish a silicon wafer, silicon oxide film must be removed first. Silicon oxide is harder than silicon and is chemically stable, and thus cannot be removed without the use of a polishing composition with high abrasive concentration.

On the other hand, if a polishing composition with high abrasive concentration is to be used, the factor by which the polishing composition is diluted cannot be raised, which means higher costs. Further, higher abrasive concentrations can lead to flaws on the wafer or to abrasives remaining on the wafer.

An object of the present invention is to provide a polishing composition capable of quickly removing oxide film even with low abrasive concentration (i.e., even when the composition is diluted by a large factor prior to use).

A polishing composition according to an embodiment of the present invention includes: silica with a silanol group density of 2.0 OH/nm² or higher; and an organic silicon compound having, at a terminal, an amino group, methylamino group, dimethylamino group or quaternary ammonium group, the organic silicon compound having two or more alkoxyl groups or hydroxyl groups bonded to an Si atom thereof. However, the quaternary ammonium group of the organic silicon compound does not have an alkyl group with a carbon number of two or more.

The present invention provides a polishing composition capable of quickly removing oxide film even with low abrasive concentration (i.e., even when the composition is diluted by a large factor prior to use).

### BRIEF DESCRIPTION OF THE DRAWINGS

FIG. 1 is a graph schematically showing how the torque current in the polishing surface plate changed over time during polishing.

FIG. 2 illustrates difference GBIR.

### EMBODIMENTS FOR CARRYING OUT THE INVENTION

To solve the above-stated problems, the present inventors conducted various investigations, and revealed that a polishing composition can be obtained that is capable of quickly removing oxide film even when the composition is diluted by a large factor prior to use by using silica with a silanol group density of 2.0 OH/nm² or higher as an abrasive, and having the polishing composition contain an organic silicon compound having, at a terminal, an amino group, a methylamino group, a dimethylamino group or a quaternary ammonium group in which the carbon number for the added alkyl group(s) is not more than 1.

Although it is not clear in which mechanism the above-stated arrangement promotes removal of oxide film, it is believed that the amino group or the like of the organic silicon compound contributes to oxide removal because an organic silicon compound with no amino group or the like at a terminal exhibits no oxide removal performance (that is, there is no difference from a composition with no organic silicon compound at all).

Further, since the number of alkoxyl groups or hydroxyl groups of the organic silicon compound and the silanol group density in the silica affect oxide removal performance, it is possible that the organic silicon compound being adsorbed on the surfaces of the silica may promote oxide removal.

It is generally known that organic silicon compounds can easily be adsorbed on silica, which allows an assumption that silica serving as an abrasives also has an organic silicon compound adsorbed thereon. On the other hand, silicon oxide film is also SiO₂, and this allows an assumption that an organic silicon compound can easily be adsorbed on silicon oxide film, too. It is assumed that, during polishing, the organic silicon compound adsorbed on the silica acts so as to be also adsorbed on the silicon oxide, allowing the abrasives to contribute to polishing more effectively.

On the other hand, the above-described oxide removal performance cannot be obtained by the use of silica that has been surface-modified with an amino group or the like in advance. This suggests that the organic silicon compound that is present in an isolated state, without being bonded to silica, may contribute to oxide removal.

This is believed to be caused by the organic silicon compound in an isolated state may be adsorbed on organic film during polishing and act to attract abrasives on the same principles.

The present invention was made based on these findings. The polishing composition according to an embodiment of the present invention will be described in detail below.

A polishing composition according to an embodiment of the present invention includes: silica with a silanol group density of 2.0 OH/nm² or higher; and an organic silicon compound having an amino group or the like at a terminal. The organic silicon compound has two or more alkoxyl groups or hydroxyl groups bonded to its Si atom(s).

[Silica]

The polishing composition according to the present embodiment contains silica. Examples of the silica include colloidal silica and fumed silica, where colloidal silica is particularly suitable. The silica is not limited to a particular size or shape (degree of association). The silica may have a secondary particle size in the range of 20 to 120 nm, for example.

The silanol group density in the silica is to be 2.0 OH/nm² or higher. An organic silicon compound is believed to be adsorbed on an —OH group of an inorganic compound. Thus, if the number of silanol groups on the silica surface is small, the organic silicon compound cannot easily be adsorbed, which means that good oxide removal performance cannot be obtained. The silanol group density in the silica is preferably not lower than 3.0 OH/nm², and more preferably not lower than 4.0 OH/nm². Silanol group density is measured by titrimetry.

Generally, the polishing composition is diluted prior to use. As such, the undiluted solution of the polishing composition can have any silica concentration. However, depending on the composition, an excessively high silica concentration in the undiluted solution can lead to aggregation during storage. On the other hand, an excessively low silica concentration in the undiluted solution means an increased bulk, which leads to increased costs for storage and transportation. Accordingly, the silica concentration in the undiluted solution of the polishing composition is preferably 0.01 to 20 weight %. The lower limit for silica concentration is more preferably 0.1 weight %, and yet more preferably 1 weight %. The upper limit for abrasive concentration is more preferably 15 weight %, and yet more preferably 12 weight %.

[Organic Silicon Compound]

The polishing composition according to the present embodiment includes an organic silicon compound having, at a terminal, an amino group, a methylamino group, a dimethylamino group or a quaternary ammonium group in which the carbon number for the added alkyl group(s) is not more than 1 (hereinafter simply referred to as “organic silicon compound”). The functional group at a terminal is limited to an amino group, a methylamino group, a dimethylamino group or a quaternary ammonium group in which the carbon number for the added alkyl group(s) is not more than 1 because the presence of a hydrocarbon group with a carbon number of 2 or more outside an amino group of the organic silicon compound would decrease oxide removal performance.

The organic silicon compound includes two or more alkoxyl groups or hydroxyl groups bonded to an Si atom thereof. Some of the alkoxyl groups bonded to an Si atom are hydrolyzed in water and become hydroxyl groups (silanol groups). These hydroxyl groups are adsorbed on the silica surfaces by hydrogen bonding. Alternatively, they undergo dehydrative condensation with silanol groups on the silica surfaces to form siloxane bonds. In this way, the organic silicon compound is adsorbed on the silica surfaces.

As will be shown in the examples further below, a low silanol group density in the silica does not result in good oxide removal performance. This gives an assumption that the silica with the organic silicon compound adsorbed on its surfaces contributes to oxide removal. If fewer than two alkoxyl groups or hydroxyl groups are bonded to an Si atom of the organic silicon compound, good oxide removal performance cannot be obtained.

Thus, the number of alkoxyl groups or hydroxyl groups bonded to an Si atom of the organic silicon compound is to be not less than 2. If the organic silicon compound includes both alkoxyl groups and hydroxyl groups bonded to an Si atom thereof, it is sufficient if the total is not less than 2. Further, the smaller the molecular weight of an alkoxyl group, the more easily hydrolysis can occur, which is preferable. Thus, the alkoxyl group is preferably a methoxy group or ethoxy group, where a methoxy group is more preferable. The number of the alkoxyl groups or hydroxyl groups bonded to an Si atom of the organic silicon compound is preferably not less than 3.

The organic silicon compound preferably has a molecular weight not more than 1,000. The molecular weight of the organic silicon compound is more preferably not more than 500, and yet more preferably not more than 300.

The organic silicon compound is preferably one in which the number of Si atoms in one molecule is not more than 2.

Specifically, an organic silicon compound as expressed by the following general formula, (1), is suitable:

X¹—(R¹—NH)ₙ—X²—Si(OR²)ₘ(R³)₃₋ₘ (1).

In the above formula, X¹ indicates an amino group, methylamino group, dimethylamino group, or quaternary ammonium group; X² indicates a single bond or a divalent hydrocarbon group with a carbon number of 1 to 8; R¹ indicates a divalent hydrocarbon group with a carbon number of 1 to 8; R² indicates a hydrogen atom or a monovalent hydrocarbon group with a carbon number of 1 to 6; R³ indicates a monovalent hydrocarbon group with a carbon number of 1 to 10; n indicates an integer of 0 to 2; and m indicates 2 or 3. However, the quaternary ammonium group of X¹ does not have an alkyl group with a carbon number of 2 or more.

In formula (1), there is a tendency that the smaller the value of n, the better the oxide removal performance. That is, n is preferably 0 or 1, where 0 is more preferable. Further, as discussed above, the alkoxyl group bonded to an Si atom is preferably a methoxy group or an ethoxy group, where a methoxy group is more preferable. That is, R² is preferably a methyl group or an ethyl group, where a methyl group is more preferable. The carbon number of R³ is preferably 1 to 6, and more preferably 1 to 3. m is preferably 3.

Specific examples of the compound of formula (1) include
N-(2-aminoethyl)-3-aminopropyltrimethoxysilane,
N-(2-aminoethyl)-3-aminopropyltriethoxysilane,
3-aminopropyltrimethoxysilane, 3-aminopropyltriethoxysilane,
N-(2-aminoethyl)-3-aminopropylmethyldimethoxysilane,
N-(2-aminoethyl)-3-aminopropylmethyldiethoxysilane,
3-aminopropylmethyldimethoxysilane, and
3-aminopropylmethyldiethoxysilane.

The organic silicon compound may be a partial hydrolysis condensate of the above-discussed organic silicon compound. That is, the organic silicon compound may be the one as expressed by the following general formula, (2):

X³—(R⁴—NH)ₖ—X⁵—Si(OR⁶)ₕ(R⁸)₂₋ₕ—O—Si(OR⁷)ᵢ(R⁹)₂₋ᵢ—X⁶—(NH—R⁵)ⱼ—X⁴ (2).

In the above formula, each of X³ and X⁴ independently indicates an amino group, methylamino group, dimethylamino group, or quaternary ammonium group; each of X⁵ and X⁶ independently indicates a single bond or a divalent hydrocarbon group with a carbon number of 1 to 8; each of R⁴ and R⁵ independently indicates a divalent hydrocarbon group with a carbon number of 1 to 8; each of R⁶ and R⁷ independently indicates a hydrogen atom or a monovalent hydrocarbon group with a carbon number of 1 to 6; each of R⁸ and R⁹ independently indicates a monovalent hydrocarbon group with a carbon number of 1 to 10; each of k and j independently indicates an integer of 0 to 2; and each of h and i independently indicates 1 or 2. However, the quaternary ammonium group of X³ and X⁴ does not have an alkyl group with a carbon number of 2 or more.

In formula (2), there is a tendency that the smaller the values of k and j, the better the oxide removal performance. That is, each of k and j is preferably 0 or 1, where 0 is more preferable. X⁵ and X⁶ are preferably a single bond. Each of h and i is preferably 2.

Examples of the compound of formula (2) include the following compounds:

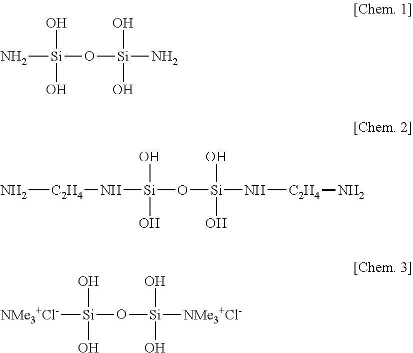

One of these organic silicon compounds may be used alone, or two or more thereof may be mixed. The concentration of the organic silicon compound (if two or more compounds are contained, their total concentration) is not limited to any particular value; for example, where the amount of silica is represented as 100 parts by weight, the concentration may be 1 to 300 parts by weight. The lower limit for the concentration of the organic silicon compound is preferably 2 parts by weight, more preferably 5 parts by weight, and yet more preferably 10 parts by weight, where the amount of silica is represented as 100 parts by weight. The upper limit for the concentration of the organic silicon compound is preferably 100 parts by weight, more preferably 50 parts by weight, and more preferably 30 parts by weight, where the amount of silica is represented as 100 parts by weight.

In the polishing composition according to the present embodiment, the molecular weight of the organic silicon compound, M, the concentration of the organic silicon compound, c_{c}, the primary particle size of the silica, d₁, the true density of the silica, ρ₀, and the concentration of the silica, cₛ, preferably satisfy the following expression:

(78260/M×c_{c})/{6/(d₁×ρ₀)×1000×cₛ}×100≥8.0,

where the unit for d₁ is nm, the unit for ρ₀ is g/cm³, and the unit for c_{c} and cₛ is weight %.

In the above expression, “6/(d₁×ρ₀)×1000” represents the specific surface area (m²/g), where it is assumed that the silica is a sphere with a diameter of d₁. “78260/M” represents the minimum area of coating of the organic silicon compound determined from the Stuart-Briegleb molecular model (m²/8). The left side of the above expression “(78260/M×c_{c})/{6/(d₁×ρ₀)×1000×cₛ}×100≥8.0” means the ratio (%) of the total minimum area of coating of the organic silicon compound in the polishing composition relative to the total surface area of the silica in the polishing composition (%). This value will be hereinafter referred to as “percentage of coating”. The percentage of coating is more preferably not less than 10%, and yet more preferably not less than 20%. The primary particle size d₁ of the silica means the average particle size obtained by the BET method.

[Basic Compound]

The polishing composition according to the present embodiment may further contain a basic compound other than the above-discussed organic silicon compound (hereinafter simply referred to as “basic compound”). The basic compound etches the surface of the wafer, mainly after the oxide film is removed, thereby achieving chemical polishing. The basic compound may be, for example, an amine compound or inorganic alkali compound.

Examples of the amine compound include primary amines, secondary amines, tertiary amines, quaternary ammonium and hydroxides thereof, and heterocyclic amines. Specific examples include ammonia, tetramethylammonium hydroxide (TMAH), tetraethylammonium hydroxide (TEAH), tetrabutylammonium hydroxide (TBAH), methylamine, dimethylamine, trimethylamine, ethylamine, diethylamine, triethylamine, hexylamine, cyclohexylamine, ethylenediamine, hexamethylenediamine, diethylenetriamine (DETA), triethylenetetramine, tetraethylenepentamine, pentaethylenehexamine, monoethanolamine, diethanolamine, triethanolamine, N-(β-aminoethyl)ethanolamine, anhydrous piperazine, piperazine hexahydrate, 1-(2-aminoethyl)piperazine, N-methylpiperazine, piperazine hydrochloride, and guanidine carbonate. DETA is particularly preferable.

Examples of the inorganic alkali compound include alkali metal hydroxides, alkali metal salts, alkaline earth metal hydroxides and alkaline earth metal salts. Specific examples of the inorganic alkaline compound include potassium hydroxide (KOH), sodium hydroxide, potassium hydrogen carbonate, potassium carbonate, sodium hydrogen carbonate, and sodium carbonate. KOH is particularly preferable.

One of these basic compounds may be used alone, or two or more thereof may be mixed. The concentration of the basic compound (if two or more compounds are contained, their total concentration) is not limited to any particular value; for example, where the amount of silica is represented as 100 parts by weight, the concentration may be 0.1 to 40 parts by weight. The lower limit for the concentration of the basic compound is preferably 1 part by weight, and more preferably 3 parts by weight, where the amount of silica is represented as 100 parts by weight. The upper limit for the concentration of the basic compound is preferably 30 parts by weight, and more preferably 20 parts by weight, where the amount of silica is represented as 100 parts by weight.

[Chelating Agent]

The polishing composition according to the present embodiment may further contain a chelating agent. The chelating agent may be, for example, an aminocarboxylic acid-based chelating agent, or an organic phosphonic acid-based chelating agent.

Specific examples of the aminocarboxylic acid-based chelating agent include ethylenediaminetetraacetic acid, sodium ethylenediaminetetraacetate, nitrilotriacetic acid, sodium nitrilotriacetate, ammonium nitrilotriacetate, hydroxyethylethylenediaminetriacetic acid, sodium hydroxyethylethylenediaminetriacetate, diethylenetriaminepentaacetic acid (DTPA), sodium diethylenetriaminepentaacetate, triethylenetetraminehexaacetic acid, and sodium triethylenetetraminehexaacetate.

Specific examples of the organic phosphonic acid-based chelating agent include 2-aminoethylphosphonic acid, 1-hydroxyethylidene-1,1-diphosphonic acid, aminotri(methylenephosphonic acid), ethylenediaminetetrakis(methylenephosphonic acid), diethylenetriaminepenta(methylenephosphonic acid), ethane-1,1, -diphosphonic acid, ethane-1,1,2-triphosphonic acid, ethane-1-hydroxy-1,1-diphosphonic acid, ethane-1-hydroxy-1,1, 2-triphosphonic acid, ethane-1,2-dicarboxy-1,2-diphosphonic acid, methanehydroxyphosphonic acid, 2-phosphonobutane-1,2-dicarboxylic acid, 1-phosphonobutane-2,3,4-tricarboxylic acid, and α-methylphosphonosuccinic acid.

[Water-Soluble Polymer]

The polishing composition according to the present embodiment may further contain a water-soluble polymer. The water-soluble polymer is adsorbed on the surface of the wafer to modify the surface of the wafer. This improves uniformity in polishing, thereby reducing surface roughness.

Examples of the water-soluble polymer include celluloses such as hydroxyethyl cellulose (HEC), hydroxyethylmethyl cellulose, hydroxypropylmethyl cellulose, carboxymethyl cellulose, cellulose acetate and methyl cellulose, vinyl polymers such as polyvinyl alcohol (PVA) and polyvinyl pyrrolidone (PVP), glycoside, polyethylene glycol, polypropylene glycol, polyglycerin (PGL), N,N,N′,N′-tetrakis polyoxyethylene polyoxypropylene ethylenediamine (poloxamine), poloxamer, polyoxyalkylene alkyl ethers, polyoxyalkylene fatty acid esters, polyoxyalkylene alkylamines, alkylene oxide derivatives of methyl glucoside, polyhydric alcohol alkylene oxide adducts, and polyhydric alcohol fatty acid esters.

Although not limiting, the concentration of the water-soluble polymer may be, for example, 0.01 to 30 parts by weight, where the amount of silica is represented as 100 parts by weight. The lower limit for the concentration of the water-soluble polymer is preferably 0.1 parts by weight, and more preferably 1 part by weight, where the amount of silica is represented as 100 parts by weight. The upper limit for the concentration of the water-soluble polymer is preferably 20 parts by weight, and more preferably 10 parts by weight, where the amount of silica is represented as 100 parts by weight.

The balance of the polishing composition according to the present embodiment is water. In addition, the polishing composition according to the present embodiment may contain any other ingredients that are generally known in the field of polishing compositions.

For example, the polishing composition according to the present embodiment may further contain a pH conditioner. Although not limiting, the pH of the polishing composition according to the present embodiment is preferably 10.0 to 12.0. Depending on the type of the silica and compound contained, there is a tendency that the lower the pH, the lower the aggregation stability. The lower limit for the pH of the polishing composition is preferably 10.5, and more preferably 11.0.

The polishing composition according to the present embodiment is prepared by appropriately mixing the silica, organic silicon compound and other ingredients and then adding water. Alternatively, the polishing composition according to the present embodiment may be prepared by successively mixing water with the abrasives, organic silicon compound and other ingredients. These ingredients may be mixed by a means that is typically used in the technical field of polishing compositions, such as a homogenizer or ultrasonics.

The polishing composition according to the present embodiment is diluted with water to be in an appropriate concentration before being used to polish a silicon wafer.

In some implementations, the polishing composition according to the present embodiment is used only during removal of oxide film on the silicon wafer. For example, the polishing composition according to the present embodiment may be used to perform the first stage of the polishing of the silicon wafer and, after the removal of oxide film, may be replaced by another polishing composition for further polishing. Typically, when one polishing composition is replaced by another, the silicon wafer must be cleaned and/or the polishing pad must be replaced by another. Since the polishing composition according to the present embodiment can be diluted by a large factor prior to use, continued polishing is possible under certain conditions, without an intermediate step such as cleaning.

Further, the polishing composition according to the present embodiment may be used as an additive for oxide removal. That is, the polishing composition according to the present embodiment may be diluted by a large factor and added to another polishing composition, or a small amount of the undiluted solution may be added without being diluted to provide the other polishing composition with the ability to remove oxide while maintaining the polishing performance of this composition.

### EXAMPLES

The present invention will be described more specifically by means of examples. The present invention is not limited to these examples.

Different types of silica, A to J shown in Table 1, and different organic silicon compounds, SA to SJ shown in Table 2, were used to prepare various polishing compositions. In Table 1, “Primary particle size” means the average particle size obtained by the BET method, while “Secondary particle size” means the average particle size obtained by dynamic light scattering (DLS). “Degree of association” means the secondary particle size divided by the primary particle size.

TABLE 1

| | Primary | Secondary | | | Specific | Silanol | |
|---|---|---|---|---|---|---|---|
| | particle | particle | | True | surface | group | |
| | size | size | Degree of | density | area | density | |
| Mark | (nm) | (nm) | association | (g/cm³) | (m²/g) | (OH/nm²) | Surface modification |
| A | 34.6 | 70 | 2.0 | 2.2 | 78.8 | 5.6 | not performed |
| B | 24.4 | 48 | 2.0 | | 111.8 | 4.2 | not performed |
| C | 58.4 | 99 | 1.7 | | 46.7 | 3.5 | not performed |
| D | 35.1 | 54 | 1.5 | | 77.7 | 5.6 | not performed |
| E | 29.7 | 84 | 2.8 | | 91.8 | 4.2 | not performed |
| F | 16.5 | 26 | 1.6 | | 165.3 | 2.6 | not performed |
| G | 30.6 | 62 | 2.0 | | 89.1 | 1.8 | not performed |
| H | 21.9 | 38 | 1.7 | | 124.5 | 1.6 | not performed |
| I | 35.6 | 67 | 1.9 | | 76.6 | — | modified with cation (amino group) |
| J | 32.9 | 68 | 2.1 | | 82.9 | — | modified with anion (sulfo group) |

TABLE 2

| | | | | Minimum area |
|---|---|---|---|---|
| | | | Molecular | of coating |
| Mark | Chemical name | Structural formula | weight | (m²/g) |
| SA | N-(2-aminoethyl)-3- aminopropyltrimethoxysilane | 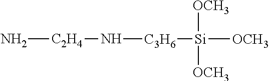 | 222.4 | 351.9 |
| SB | N-(2-aminoethyl)-3- aminopropylmethyldimethoxysilane | 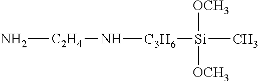 | 206.4 | 379.2 |
| SC | 3-aminopropyltrimethoxysilane | 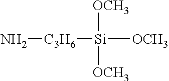 | 179.3 | 436.5 |
| SD | 3-aminopropyltriethoxysilane | 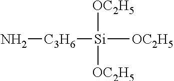 | 221.4 | 353.5 |
| SE | — | 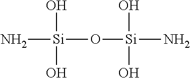 | 172.2 | 454.5 |
| SF | — | 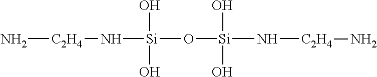 | 258.4 | 302.9 |
| SG | — | 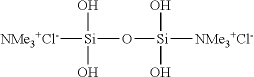 | 329.3 | 237.7 |
| SH | N-(2-aminoethyl)-3- aminopropyltriethoxysilane | 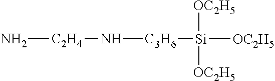 | 264.5 | 295.9 |
| SI | 3-triethoxysilyl-(1,3-dimethyl- butylidene)propylamine | 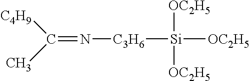 | 303.5 | 257.9 |
| SJ | N-phenyl-3-aminopropyltrimethoxysilane | 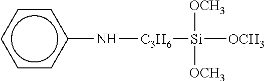 | 255.4 | 306.0 |

[Aggregation Stability Test]

The various polishing compositions (undiluted) were left undisturbed in a 50° C. atmosphere for 30 days, and were evaluated based on the difference between the initial average particle size and the average particle size after the 30-day period at 50° C. Average particle size was measured using dynamic light scattering (secondary particle size), and was measured by a particle-size measurement system “ELS-Z2” from Otsuka Elctronics Co. Ltd. A composition with an increase in average particle size below 10% was judged to be good, and a composition with an increase larger than 10% unsatisfactory (“unsat.”).

[Polishing Test]

The various polishing compositions were used to polish plane (100) of a p-type silicon wafer with a diameter of 300 mm. The polishing equipment used was a PNX332B from Okamoto Machine Tool Works, Ltd. The polishing pad used was a urethane polishing pad. The polishing composition was diluted with water by a predetermined factor, and was supplied at a supply rate of 0.6 l/min. Polishing was performed for four minutes, where the rate of rotation of the surface plate was 40 rpm, the rate of rotation of the head 39 rpm, the load on the guide 0.020 MPa, and the load on the wafer 0.015 MPa.

During polishing of a silicon wafer, first, natural oxide film that has been formed on the surface of the silicon wafer is removed, before the silicon single crystals are polished. The time required for oxide removal (hereinafter referred to as “oxide removal time”) was determined in the following manner.

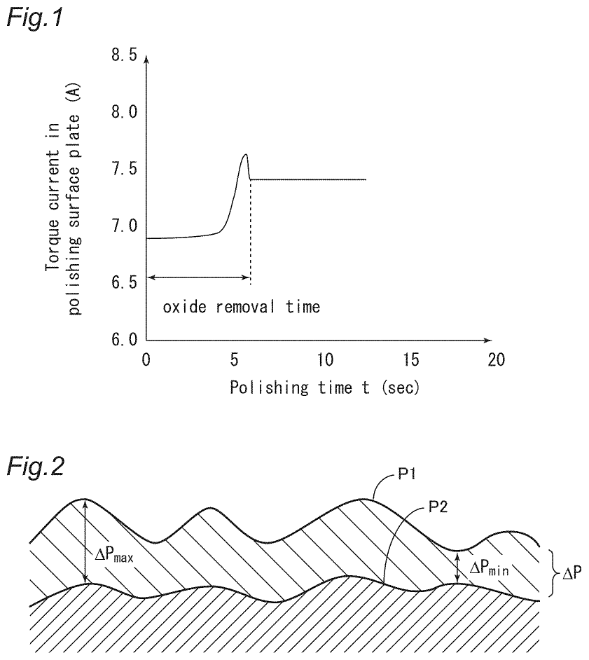

FIG. 1 is a graph schematically showing how the torque current in the polishing surface plate changed over time during polishing. During polishing, readings of the torque current for rotating the polishing surface plate and the load on the polishing head were recorded at intervals of 0.5 seconds. The point of time at which the load on the polishing head reached a set level (0.020 MPa) was treated as the polishing start time (t=0). The torque current in the polishing surface plate was automatically controlled to provide a constant rate of rotation. Thus, when the friction between the wafer and polishing pad increased, the torque current increased; when the friction decreased, the torque current decreased. Since the polishing behavior for oxide film is different from that for silicon single crystals, the torque current in a polishing surface plate shows a discontinuity at the border between these two stages. The time from the polishing start time (t=0) until the stabilization of the torque current in the polishing surface plate was treated as oxide removal time.

Upon completion of polishing, non-contact surface-roughness measurement equipment (Wyco NT9300 from Veeco Instruments Inc.) was used to measure the surface roughness of the silicon wafer, Ra.

The wafer shape was evaluated based on “difference GBIR”, discussed below.

FIG. 2 illustrates difference GBIR. First, the profile of the thickness (i.e., distance from the back reference plane) of the silicon wafer prior to polishing, P1, was measured. Similarly, the profile of the thickness of the silicon wafer after polishing, P2, was measured. The difference between the pre-polish profile P1 and the post-polish profile P2 was determined to calculate the profile of the thickness of material removed by polishing (i.e., amount of removal), ΔP. The difference between the maximum value of the profile ΔP of the amount of removal within the region excluding predetermined edge areas, ΔPₘₐₓ, and the minimum value, ΔPₘᵢₙ, was treated as “difference GBIR”.

Evaluating the wafer shape based on difference GBIR mitigates the effects of variations and irregularities in the pre-polish silicon wafer compared with evaluation based on normal GBIR, enabling more accurate evaluation of the polishing step itself.

The thickness profiles of the silicon wafer prior to and after polishing were measured by a wafer flatness tester (Nanometro 300TT-A from Kuroda Precision Industries Ltd.). The average thickness of removal divided by the polishing time was treated as polishing rate.

[Test Results]

First, the polishing compositions labeled Test Nos. 1 to 4, shown in Table 3, were used to investigate the effects of the organic silicon compound on the oxide removal performance.

TABLE 3

| Test No. | | | 1 | 2 | 3 | 4 |
|---|---|---|---|---|---|---|
| Undiluted | Abrasives (silica) | Type | A | | | |
| solution | | Concentration (wt %) | 9.0 | | | |
| | Chelating agent | Type | DTPA | | | |
| | | Concentration (wt %) | 0.06 | | | |
| | Basic compound | Type | KOH | | | |
| | | Concentration (wt %) | 0.40 | | | |
| | | Ratio to abrasives | 4.4 | | | |
| | Organic silicon | Type | — | SA | | |
| | compound | Concentration (wt %) | — | 0.9 | 0.6 | 0.3 |
| | | Ratio to abrasives | — | 10.0 | 6.7 | 3.3 |

| | | | | |
|---|---|---|---|---|
| pH | 10.26 | 10.69 | 10.70 | 10.63 |
| Aggregation stability | good | unsat. | good | good |

| Total surface area of abrasives (m²) | 709.2 | | | |
|---|---|---|---|---|
| Total minimum area of coating (m²) | — | 316.7 | 211.1 | 105.6 |
| Percentage of coating (%) | — | 44.7 | 29.8 | 14.9 |
| Dilution factor | 61 | | | |
| POU abrasive concentration (wt %) | 0.15 | | | |
| Oxide removal time (sec) | 48 | 1 | 3 | 13 |
| Polishing rate (μm/min) | 0.08 | 0.26 | 0.22 | 0.12 |
| Ra (nm) | 0.24 | 0.35 | 0.30 | 0.23 |
| Difference GBIR (μm) | 0.15 | 0.21 | 0.19 | 0.17 |
| Additional info | comp. ex. | inv. ex. | inv. ex. | inv. ex. |

The rows “Ratio to abrasives” for “Basic compound” and “Organic silicon compound” in Table 3 indicate the ratio of the weight of abrasives to the weight of silica, rather than to the total weight, where the weight of the silica is represented as 100. Further, the row “Total surface area of abrasives” indicates the total surface area of the silica for 100 g of the polishing composition (undiluted). “Total minimum area of coating” indicates the total minimum area of coating of the organic silicon compound for 100 g of the polishing composition (undiluted). The row “Percentage of coating” indicates the total minimum area of coating divided by the total surface area of the abrasives and multiplied by 100. The row “POU abrasive concentration” indicates the silica concentration at a point of use, i.e., after dilution. All this applies to Tables 4 to 14 shown below.

A comparison between Test No. 1 and Test Nos. 2 to 4 shows that adding the organic silicon compound significantly reduced the oxide removal time. A comparison among Test Nos. 2 to 4 shows that the higher the concentration of the organic silicon compound, the shorter the oxide removal time. It also shows that the higher the concentration of the organic silicon compound, the higher the polishing rate.

Next, the polishing compositions labeled Test Nos. 3 and 5 to 7, shown in Table 4, were used to investigate the relationship between the dilution factor and oxide removal performance.

TABLE 4

| | | | | |
|---|---|---|---|---|
| Test No. | 3 | 5 | 6 | 7 |

| | | | |
|---|---|---|---|
| Undiluted | Abrasives | Type | A |
| solution | (silica) | Concentration (wt %) | 9.0 |
| | Chelating agent | Type | DTPA |
| | | Concentration (wt %) | 0.06 |
| | Basic compound | Type | KOH |
| | | Concentration (wt %) | 0.40 |
| | | Ratio to abrasives | 4.4 |
| | Organic silicon | Type | SA |
| | compound | Concentration (wt %) | 0.6 |
| | | Ratio to abrasives | 6.7 |

| Total surface area of abrasives (m²) | 709.2 | | | |
|---|---|---|---|---|
| Total minimum area of coating (m²) | 211.1 | | | |
| Percentage of coating (%) | 29.8 | | | |
| Dilution factor | 61 | 91 | 121 | 151 |
| POU abrasive concentration (wt %) | 0.15 | 0.10 | 0.07 | 0.06 |
| Oxide removal time (sec) | 3 | 3 | 3 | 2 |
| Polishing rate (μm/min) | 0.22 | 0.20 | 0.16 | 0.14 |
| Ra (nm) | 0.30 | 0.25 | 0.24 | 0.23 |
| Difference GBIR (μm) | 0.19 | 0.16 | 0.13 | 0.15 |
| Additional info | inv. ex. | inv. ex. | inv. ex. | inv. ex. |

As shown in Table 4, the oxide removal performance was maintained even for higher dilution factors (i.e., lower concentrations of the silica and organic silicon compound).

Next, the polishing compositions labeled Test Nos. 8 to 18, shown in Table 5, were used to investigate the relationship between the type of the organic silicon compound and the oxide removal performance.

TABLE 5

| Test No. | | | 8 | 9 | 10 | 11 | 12 | 13 | 14 | 15 | 16 | 17 | 18 |
|---|---|---|---|---|---|---|---|---|---|---|---|---|---|
| Undiluted | Abrasives | Type | A | | | | | | | | | | |
| solution | (silica) | Concen- | 9.0 | | | | | | | | | | |
| | | tration | | | | | | | | | | | |
| | | (wt %) | | | | | | | | | | | |
| | Chelating | Type | DTPA | | | | | | | | | | |
| | agent | Concen- | 0.06 | | | | | | | | | | |
| | | tration | | | | | | | | | | | |
| | | (wt %) | | | | | | | | | | | |
| | Basic | Type | KOH | | | | | | | | | | |
| | compound | Concen- | 0.50 | | | | | | | | | | |
| | | tration | | | | | | | | | | | |
| | | (wt %) | | | | | | | | | | | |
| | | Ratio to | 5.6 | | | | | | | | | | |
| | | abrasives | | | | | | | | | | | |
| | Organic | Type | — | SA | SB | SC | SD | SE | SF | SG | SH | SI | SJ |
| | silicon | Concen- | — | 0.6 | | | | | | | | | |
| | compound | tration | | | | | | | | | | | |
| | | (wt %) | | | | | | | | | | | |
| | | Ratio to | — | 6.7 | | | | | | | | | |
| | | abrasives | | | | | | | | | | | |

| | | | | | | | | | | | |
|---|---|---|---|---|---|---|---|---|---|---|---|
| pH | 10.56 | 10.93 | 11.00 | 11.02 | 11.03 | 11.00 | 10.91 | 10.64 | 10.93 | 10.90 | 10.55 |
| Aggregation | good | good | good | unsat. | unsat. | unsat. | good | unsat. | good | good | unsat. |
| stability | | | | | | | | | | | |

| Total surface area | 709.2 | | | | | | | | | | |
|---|---|---|---|---|---|---|---|---|---|---|---|
| of abrasives (m²) | | | | | | | | | | | |
| Total minimum area | — | 211.1 | 227.5 | 261.9 | 212.1 | 272.7 | 181.74 | 142.62 | 177.5 | 154.74 | 183.6 |
| of coating (m²) | | | | | | | | | | | |
| Percentage of coating (%) | — | 29.8 | 32.1 | 36.9 | 29.9 | 38.5 | 25.6 | 20.1 | 25.0 | 21.8 | 25.9 |
| Dilution factor | 61 | | | | | | | | | | |
| POU abrasive | 0.15 | | | | | | | | | | |
| concentration (wt %) | | | | | | | | | | | |
| Oxide removal time (sec) | 163 | 6 | 40 | 1 | 5 | 1 | 3 | 20 | 13 | 122 | 92 |
| Polishing rate (μm/min) | 0.05 | 0.20 | 0.21 | 0.15 | 0.13 | 0.16 | 0.18 | 0.17 | 0.18 | 0.05 | 0.05 |
| Ra (nm) | 0.25 | 0.25 | 0.24 | 0.25 | 0.23 | 0.22 | 0.25 | 1.51 | 0.24 | 0.20 | 0.19 |
| Difference GBIR (μm) | 0.16 | 0.22 | 0.17 | 0.18 | 0.17 | 0.23 | 0.35 | 0.67 | 0.30 | 0.19 | 0.09 |
| Additional info | comp. | inv. ex. | inv. ex. | inv. ex. | inv. ex. | inv. ex. | inv. ex. | inv. ex. | inv. ex. | comp. | comp. |
| | ex. | | | | | | | | | ex. | ex. |

A comparison between Test No. 9 (the organic silicon compound being N-(2-aminoethyl)-3-aminopropyltrimethoxysilane) and Test No. 16 (the organic silicon compound being N-(2-aminoethyl)-3-aminopropyltriethoxysilane), and a comparison between Test No. 11 (the organic silicon compound being 3-aminopropyltrimethoxysilane) and Test No. 12 (the organic silicon compound being 3-aminopropyltriethoxysilane) show that better oxide removal performances were achieved when the alkoxyl group was a methoxy group (Test Nos. 9 and 11), rather than an ethoxy group (Test Nos. 16 and 12).

A comparison between Test No. 9 (the organic silicon compound being N-(2-aminoethyl)-3-aminopropyltrimethoxysilane) and Test No. 11 (the organic silicon compound being 3-aminopropyltrimethoxysilane), and a comparison between Test No. 16 (the organic silicon compound being N-(2-aminoethyl)-3-aminopropyltriethoxysilane) and Test No. 12 (the organic silicon compound being 3-aminopropyltriethoxysilane) show that a better oxide removal performance was achieved when the value of n in general formula (1) was 0, rather than 1.

A comparison between Test No. 9 (the organic silicon compound being N-(2-aminoethyl)-3-aminopropyltrimethoxysilane) and Test No. 10 (the organic silicon compound being N-(2-aminoethyl)-3-aminopropylmethyldimethoxysilane) shows that a better oxide removal performance was achieved when the number of alkoxyl groups of the organic silicon compound was 3 (Test No. 9).

The polishing composition of Test No. 17 (the organic silicon compound being 3-triethoxy silyl-(1,3-dimethyl-butylidene)propylamine) and Test No. 18 (the organic silicon compound being N-phenyl-3-aminopropyltrimethoxysilane) had poor oxide removal performances compared with the other polishing compositions. This is presumably because bulky functional groups were attached around the amino groups of the organic silicon compound, causing steric hindrance, which weakened the reactivity of the amine.

Next, the polishing compositions labeled Test Nos. 19 to 24 shown in Table 6 were used to investigate the relationship between the concentration of the basic compound (KOH) and the oxide removal performance.

TABLE 6

| Test No. | | | 19 | 20 | 21 | 22 | 23 | 24 |
|---|---|---|---|---|---|---|---|---|
| Undiluted | Abrasives | Type | A | | | | | |
| solution | (silica) | Concentration (wt %) | 9.0 | | | | | |
| | Chelating agent | Type | DTPA | | | | | |
| | | Concentration (wt %) | 0.18 | | | | | |
| | Basic compound | Type | KOH | | | | | |
| | | Concentration (wt %) | 0.50 | 0.65 | 0.80 | 0.95 | 1.10 | 0.65 |
| | | Ratio to abrasives | 5.6 | 7.2 | 8.9 | 10.6 | 12.2 | 7.2 |

| | | | |
|---|---|---|---|
| Organic silicon | Type | SA | — |
| compound | Concentration (wt %) | 1.8 | — |
| | Ratio to abrasives | 20.0 | — |

| | | | | | | |
|---|---|---|---|---|---|---|
| pH | 10.57 | 10.84 | 11.03 | 11.20 | 11.32 | 10.57 |
| Aggregation stability | unsat. | good | good | good | good | good |

| Total surface area of abrasives (m²) | 709.2 | | | | | |
|---|---|---|---|---|---|---|
| Total minimum area of coating (m²) | 633.4 | | | | | — |
| Percentage of coating (%) | 89.3 | | | | | — |
| Dilution factor | 181 | | | | | |
| POU abrasive concentration (wt %) | 0.05 | | | | | |
| Oxide removal time (sec) | 1 | 2 | 1 | 3 | 2 | 142 |
| Polishing rate (μm/min) | 0.22 | 0.22 | 0.21 | 0.21 | 0.20 | 0.03 |
| Ra (nm) | 0.26 | 0.27 | 0.24 | 0.24 | 0.25 | 0.27 |
| Difference GBIR (μm) | 0.20 | 0.22 | 0.24 | 0.23 | 0.25 | 0.09 |
| Additional info | inv. ex. | inv. ex. | inv. ex. | inv. ex. | inv. ex. | comp. ex. |

As shown in Table 6, changes in the concentration of the basic compound did not affect the oxide removal performance. A tendency was observed that the lower the pH, the lower the aggregation stability.

Next, the polishing compositions labeled Test Nos. 20 and 24 to 29, shown in Table 7, were used to investigate the time required to remove oxide film for yet larger changes in dilution factor.

TABLE 7

| | | | | | | | |
|---|---|---|---|---|---|---|---|
| Test No. | 24 | 25 | 26 | 27 | 20 | 28 | 29 |

| Undiluted | Abrasives | Type | A | |
|---|---|---|---|---|
| solution | (silica) | Concentration (wt. %) | 9.0 | |
| | Chelating agent | Type | DTPA | |
| | | Concentration (wt. %) | 0.18 | |
| | Basic compound | Type | KOH | |
| | | Concentration (wt. %) | 0.65 | |
| | | Ratio to abrasives | 7.2 | |
| | Organic silicon | Type | — | SA |
| | compound | Concentration (wt. %) | — | 1.8 |
| | | Ratio to abrasives | — | 20.0 |

| Total surface area of abrasives (m²) | 709.2 | | | | | | |
|---|---|---|---|---|---|---|---|
| Total minimum area of coating (m²) | — | 633.4 | | | | | |
| Percentage of coating (%) | — | 89.3 | | | | | |
| Dilution factor | 181 | 31 | 61 | 121 | 181 | 361 | 901 |
| POU abrasive concentration (wt. %) | 0.05 | 0.29 | 0.15 | 0.07 | 0.05 | 0.02 | 0.01 |
| Oxide removal time (sec) | 142 | 12 | 4 | 1 | 2 | 5 | 14 |
| Polishing rate (μm/min) | 0.03 | 0.35 | 0.31 | 0.27 | 0.22 | 0.19 | 0.14 |
| Ra (nm) | 0.27 | 0.31 | 0.30 | 0.30 | 0.27 | 0.27 | 0.23 |
| Difference GBIR (μm) | 0.09 | 0.20 | 0.23 | 0.28 | 0.22 | 0.23 | 0.19 |
| Additional info | comp. ex. | inv. ex. | inv. ex. | inv. ex. | inv. ex. | inv. ex. | inv. ex. |

As shown in Table 7, the oxide removal performance was maintained at certain levels, even for a dilution factor of 901. Further, although the reason is not clear, a tendency was observed that an excessively low dilution factor lowered the oxide removal performance. Particularly good oxide removal performance was achieved for a dilution factor in the range of 121 to 181 (i.e., POU abrasive concentration in the range of 0.05 to 0.07 weight %).

Next, the polishing compositions labeled Test Nos. 20 and 30 to 36, shown in Table 8, were used to investigate the relationship between the type of silica and the oxide removal performance.

TABLE 8

| Test No. | | | 20 | 30 | 31 | 32 | 33 | 34 | 35 | 36 |
|---|---|---|---|---|---|---|---|---|---|---|
| Undiluted | Abrasives | Type | A | B | C | D | E | F | G | H |

| | | | |
|---|---|---|---|
| solution | (silica) | Concentration (wt %) | 9.0 |
| | Chelating agent | Type | DTPA |
| | | Concentration (wt %) | 0.18 |
| | Basic compound | Type | KOH |
| | | Concentration (wt %) | 0.65 |
| | | Ratio to abrasives | 7.2 |
| | Organic silicon | Type | SA |
| | compound | Concentration (wt %) | 1.8 |
| | | Ratio to abrasives | 20.0 |

| Total surface area of abrasives (m²) | 709.2 | 1006.2 | 420.3 | 699.3 | 826.2 | 1487.7 | 801.9 | 1120.5 |
|---|---|---|---|---|---|---|---|---|
| Total minimum area of coating (m²) | 633.42 | | | | | | | |
| Percentage of coating (%) | 89.3 | 63.0 | 150.7 | 90.6 | 76.7 | 42.6 | 79.0 | 56.5 |
| Dilution factor | 181 | | | | | | | |
| POU abrasive concentration (wt %) | 0.05 | | | | | | | |
| Oxide removal time (sec) | 2 | 2 | 2 | 5 | 4 | 1 | 21 | 16 |
| Polishing rate (μm/min) | 0.22 | 0.24 | 0.24 | 0.22 | 0.24 | 0.22 | 0.22 | 0.21 |
| Ra (nm) | 0.27 | 0.30 | 0.31 | 0.29 | 0.29 | 0.29 | 0.28 | 0.28 |
| Difference GBIR (μm) | 0.22 | 0.26 | 0.22 | 0.27 | 0.26 | 0.27 | 0.24 | 0.23 |
| Additional info | inv. ex. | inv. ex. | inv. ex. | inv. ex. | inv. ex. | inv. ex. | comp. ex. | comp. ex. |

The polishing compositions labeled Test Nos. 35 and 36 had poor oxide removal performances compared with the polishing compositions labeled Test Nos. 20 and 30 to 34. This is presumably because the silanol group density on the silica surfaces in these polishing compositions was too low.

Next, the polishing compositions labeled Test Nos. 20 and 37 to 39, shown in Table 9, were used to investigate the effects of the addition of the water-soluble polymer on the oxide removal performance. The row “Ratio relative to abrasives” for “Water-soluble polymer” in Table 9 indicates the ratio of the weight of abrasives to the weight of silica, rather than to the total weight, where the weight of the silica is represented as 100.

TABLE 9

| Test No. | | | 20 | 37 | 38 | 39 |
|---|---|---|---|---|---|---|
| Undiluted | Abrasives | Type | A | | | |
| solution | (silica) | Concentration (wt %) | 9.0 | | | |
| | Chelating agent | Type | DTPA | | | |
| | | Concentration (wt %) | 0.18 | | | |
| | Basic compound | Type | KOH | | | |
| | | Concentration (wt %) | 0.65 | | | |
| | | Ratio to abrasives | 7.2 | | | |
| | Organic silicon | Type | SA | | | |
| | compound | Concentration (wt %) | 1.8 | | | |
| | | Ratio to abrasives | 20.0 | | | |
| | Water-soluble | Type | — | HEC | PVA | PGL |
| | polymer | Concentration (wt %) | — | 0.36 | | |
| | | Ratio to abrasives | — | 4.0 | | |
| | | Total surface area of abrasives (m²) | 709.2 | | | |
| | | Total minimum area of coating (m²) | 633.42 | | | |
| | | Percentage of coating (%) | 89.3 | | | |
| | | Dilution factor | 181 | | | |
| | | POU abrasive concentration (wt %) | 0.05 | | | |
| | | Oxide removal time (sec) | 2 | 3 | 3 | 8 |
| | | Polishing rate (μm/min) | 0.22 | 0.10 | 0.18 | 0.09 |
| | | Ra (nm) | 0.27 | 0.16 | 0.25 | 0.15 |
| | | Difference GBIR (μm) | 0.22 | 0.14 | 0.33 | 0.12 |
| | | Additional info | inv. ex. | inv. ex. | inv. ex. | inv. ex. |

As shown in Table 9, the oxide removal performance was not impaired by the addition of the water-soluble polymer.

Next, the polishing compositions labeled Test Nos. 27, 40 and 41, shown in Table 10, were used to investigate the relationship between the type of basic compound and the oxide removal performance.

TABLE 10

| Test No. | | | 40 | 27 | 41 |
|---|---|---|---|---|---|
| Undiluted | Abrasives | Type | A | | |
| solution | (silica) | Concentration | 4.5 | 9.0 | 6.0 |
| | | (wt %) | | | |
| | Chelating | Type | DTPA | | |
| | agent | Concentration | 0.03 | 0.18 | 0.02 |
| | | (wt %) | | | |
| | Basic | Type | KOH | KOH | DETA |
| | compound | Concentration | 0.20 | 0.65 | 1.00 |
| | | (wt %) | | | |
| | | Ratio to abrasives | 4.4 | 7.2 | 16.7 |
| | Organic | Type | SA | | |
| | silicon | Concentration | 0.3 | 1.8 | 0.3 |
| | compound | (wt %) | | | |
| | | Ratio to abrasives | 6.7 | 20.0 | 5.0 |

| | | | |
|---|---|---|---|
| Total surface area of abrasives (m²) | 354.6 | 709.2 | 472.8 |
| Total minimum area of coating (m²) | 105.6 | 633.4 | 105.6 |
| Percentage of coating (%) | 29.8 | 89.3 | 22.3 |
| Dilution factor | 31 | 121 | 121 |
| POU abrasive concentration (wt %) | 0.15 | 0.07 | 0.05 |
| Oxide removal time (sec) | 9 | 1 | 1 |
| Polishing rate (μm/min) | 0.23 | 0.27 | 0.27 |
| Ra (nm) | 0.29 | 0.30 | 0.31 |
| Difference GBIR (μm) | 0.13 | 0.28 | 0.21 |
| Additional info | inv. ex. | inv. ex. | inv. ex. |

As shown in Table 10, the oxide removal performance was not affected by a change of the basic compound from an inorganic alkali compound (KOH) to an amine compound (DETA).

Next, the polishing compositions labeled Test Nos. 20, 24, 42 and 43, shown in Table 11, were used to investigate whether similar levels of oxide removal performance can be achieved if the addition of the organic silicon compound is replaced by the use of silica that has been surface-modified with an amino group or the like in advance.

TABLE 11

| Test No. | | | 24 | 42 | 43 | 20 |
|---|---|---|---|---|---|---|
| Undiluted | Abrasives | Type | A | I | J | A |

| solution | (silica) | Concentration (wt %) | 9.0 | |
|---|---|---|---|---|
| | Chelating agent | Type | DTPA | |
| | | Concentration (wt %) | 0.18 | |
| | Basic compound | Type | KOH | |
| | | Concentration (wt %) | 0.65 | |
| | | Ratio to abrasives | 7.2 | |
| | Organic silicon | Type | — | SA |
| | compound | Concentration (wt %) | — | 1.8 |
| | | Ratio to abrasives | — | 20.0 |

| | | | | |
|---|---|---|---|---|
| pH | 10.62 | 10.84 | 10.44 | 10.84 |
| Aggregation stability | good | good | good | good |

| Total surface area of abrasives (m²) | 709.2 | 689.4 | 746.1 | 709.2 |
|---|---|---|---|---|
| Total minimum area of coating (m²) | — | — | — | 633.4 |
| Percentage of coating (%) | — | — | — | 89.3 |
| Dilution factor | 181 | | | |
| POU abrasive concentration (wt %) | 0.05 | | | |
| Oxide removal time (sec) | 142 | 94 | 80 | 2 |
| Polishing rate (μm/min) | 0.03 | 0.05 | 0.06 | 0.22 |
| Ra (nm) | 0.27 | 0.23 | 0.23 | 0.27 |
| Difference GBIR (μm) | 0.09 | 0.11 | 0.16 | 0.22 |
| Additional info | comp. ex. | comp. ex. | comp. ex. | inv. ex. |

The times required to remove oxide film for the polishing compositions each using silica that had been surface-modified with an amino group or sulfo group in advance (Test Nos. 42 and 43) were shorter than that for Test No. 24, but significantly longer than that for Test No. 20. This shows that levels of oxide removal performance comparable to compositions having the organic silicon compound cannot be achieved by using silica that has been surface-modified with an amino group or the like in advance.

Next, the polishing compositions labeled Test Nos. 20 and 44 to 49, shown in Table 12, were used to investigate the relationship between the concentration of the organic silicon compound and the oxide removal performance for larger changes in the compound concentration. “-” in the row for aggregation stability indicates that aggregation stability was not measured. The same applies to Tables 13 and 14, shown further below.

TABLE 12

| Test No. | | | 44 | 45 | 20 | 46 | 47 | 48 | 49 |
|---|---|---|---|---|---|---|---|---|---|
| Undiluted | Abrasives | Type | A | | | | | | |
| solution | (silica) | Concentration (wt %) | 9.0 | | | | | | 1.8 |
| | Chelating agent | Type | DTPA | | | | | | |
| | | Concentration (wt %) | 0.18 | | | | | | |
| | Basic compound | Type | KOH | | | | | | NH₄OH |
| | | Concentration (wt. %) | 0.65 | | | | | | 0.50 |
| | | Ratio to abrasives | 7.2 | | | | | | 27.8 |
| | Organic silicon | Type | SA | | | | | | |
| | compound | Concentration (wt %) | 0.3 | 0.6 | 1.8 | 3.6 | 7.5 | 15.0 | 0.12 |
| | | Ratio to abrasives | 3.3 | 6.7 | 20.0 | 40.0 | 83.3 | 166.7 | 6.7 |

| | | | |
|---|---|---|---|
| Water-soluble | Type | — | HEC |
| polymer | Concentration (wt %) | — | 0.36 |
| | Ratio to abrasives | — | 20 |

| | | | | | | | |
|---|---|---|---|---|---|---|---|
| pH | 11.05 | 11.09 | 10.84 | 10.96 | 10.98 | 11.05 | — |
| Aggregation stability | good | good | good | good | good | good | — |

| Total surface area of abrasives (m²) | 709.2 | | | | | | 141.8 |
|---|---|---|---|---|---|---|---|
| Total minimum area of coating (m²) | 105.6 | 211.1 | 633.4 | 1266.8 | 2639.3 | 5278.5 | 42.2 |
| Percentage of coating (%) | 14.9 | 29.8 | 89.3 | 178.6 | 372.1 | 744.3 | 29.8 |
| Dilution factor | 181 | | | | | | |
| POU abrasive concentration (wt. %) | 0.05 | | | | | | 0.01 |
| Oxide removal time (sec) | 14 | 1 | 2 | 1 | 1 | 1 | 11 |
| Polishing rate (μm/min) | 0.09 | 0.15 | 0.22 | 0.28 | 0.31 | 0.38 | 0.04 |
| Ra (nm) | 0.22 | 0.26 | 0.27 | 0.39 | 0.34 | 0.39 | 0.14 |
| Difference GBIR (μm) | 0.09 | 0.11 | 0.22 | 0.15 | 0.19 | 0.44 | 0.09 |
| Additional info | inv. ex. | inv. ex. | inv. ex. | inv. ex. | inv. ex. | inv. ex. | inv. ex. |

Table 12 shows that good oxide removal performance was maintained even when the concentration of the organic silicon compound was increased or decreased.

Further, Test No. 49 shows that good oxide removal performance can be achieved if the concentrations of the abrasives and the organic silicon compound are reduced and a water-soluble polymer is added.

Next, the polishing compositions labeled Test Nos. 20, 48, 50 and 51, shown in Table 13, were used to investigate oxide removal performance for even lower POU abrasive concentrations.

TABLE 13

| Test No. | | | 20 | 48 | 50 | 51 |
|---|---|---|---|---|---|---|
| Undiluted | Abrasives | Type | A | | | |
| solution | (silica) | Concentration (wt %) | 9.0 | | 3.0 | 1.0 |
| | Chelating agent | Type | DTPA | | | |
| | | Concentration (wt %) | 0.18 | | | |
| | Basic compound | Type | KOH | | | |
| | | Concentration (wt %) | 0.65 | | | |
| | | Ratio to abrasives | 7.2 | | 21.7 | 65.0 |
| | Organic silicon | Type | SA | | | |
| | compound | Concentration (wt %) | 1.8 | 15.0 | 15.0 | 15.0 |
| | | Ratio to abrasives | 20.0 | 166.7 | 500.0 | 1500.0 |

| | | | | |
|---|---|---|---|---|
| pH | 10.84 | 11.07 | 11.29 | 11.39 |
| Aggregation stability | good | good | — | — |

| Total surface area of abrasives (m²) | 709.2 | | 236.4 | 78.8 |
|---|---|---|---|---|
| Total minimum area of coating (m²) | 633.4 | 5278.5 | | |
| Percentage of coating (%) | 89.3 | 744.3 | 2232.9 | 6698.6 |
| Dilution factor | 181 | | | |
| POU abrasive concentration (wt %) | 0.05 | 0.05 | 0.02 | 0.01 |
| Oxide removal time (sec) | 2 | 1 | 1 | 1 |
| Polishing rate (μm/min) | 0.22 | 0.40 | 0.38 | 0.36 |
| Ra (nm) | 0.27 | 0.37 | 0.42 | 0.53 |
| Difference GBIR (μm) | 0.22 | 0.34 | 0.34 | 0.33 |
| Additional info | inv. ex. | inv. ex. | inv. ex. | inv. ex. |

Table 13 shows that the oxide removal performance was maintained even for low POU abrasive concentrations as long as a sufficient amount of the organic silicon compound was present relative to the silica. On the other hand, excessively large amounts of the organic silicon compound relative to the silica tended to increase Ra. Further, dissolution of the silica during aggregation stability testing was observed in Test Nos. 50 and 51. This shows that the concentration of the organic silicon compound is preferably not higher than 300 parts by weight, where the amount of silica is represented as 100 parts by weight.

Lastly, the polishing compositions labeled Test Nos. 21, 52 and 53 shown in Table 14 were used to investigate the amount of the organic silicon compound relative to the silica and the oxide removal performance.

TABLE 14

| Test No. | | | 21 | 52 | 53 |
|---|---|---|---|---|---|
| Undiluted | Abrasives | Type | A | | |
| solution | (silica) | Concentration | 9.0 | 9.0 | 15.0 |
| | | (wt %) | | | |
| | Chelating | Type | DTPA | | |
| | agent | Concentration | 0.18 | | |
| | | (wt %) | | | |
| | Basic | Type | KOH | | |
| | compound | Concentration | 0.80 | 0.50 | 0.40 |
| | | (wt %) | | | |
| | | Ratio to abrasives | 8.9 | 5.6 | 2.7 |
| | Organic | Type | SA | | |
| | silicon | Concentration | 1.8 | 0.3 | 0.3 |
| | compound | (wt %) | | | |
| | | Ratio to abrasives | 20.0 | 3.3 | 2.0 |

| | | | |
|---|---|---|---|
| pH | 11.03 | 10.67 | 9.45 |
| Aggregation stability | good | — | — |

| Total surface area of abrasives (m²) | 709.2 | | 1182.0 |
|---|---|---|---|
| Total minimum area of coating (m²) | 633.4 | 105.6 | |
| Percentage of coating (%) | 89.3 | 14.9 | 8.9 |
| Dilution factor | 181 | | |
| POU abrasive concentration (wt %) | 0.05 | 0.05 | 0.08 |
| Oxide removal time (sec) | 1 | 8 | 15 |
| Polishing rate (μm/min) | 0.21 | 0.08 | 0.05 |
| Ra (nm) | 0.24 | 0.25 | 0.23 |
| Difference GBIR (μm) | 0.24 | 0.07 | 0.09 |
| Additional info | inv. ex. | inv. ex. | inv. ex. |

Table 14 demonstrates that the oxide removal performance was maintained even when the concentration of the organic silicon compound was as low as 2.0 parts by weight, where the amount of silica is represented as 100 parts by weight.

Embodiments of the present invention have been described. The above-described embodiments are exemplary only, intended to allow the present invention to be carried out. Accordingly, the present invention is not limited to the above-described embodiments, and the above-described embodiments, when carried out, may be modified as appropriate without departing from the spirit of the invention.

1. A polishing composition, comprising:
silica with a silanol group density of 2.0 OH/nm² or higher; and
an organic silicon compound having, at a terminal, an amino group, methylamino group, dimethylamino group or quaternary ammonium group,
the organic silicon compound having two or more alkoxyl groups or hydroxyl groups bonded to an Si atom thereof,
wherein the quaternary ammonium group of the organic silicon compound does not have an alkyl group with a carbon number of two or more.

2. The polishing composition according to claim 1, wherein the organic silicon compound includes three or more alkoxyl groups or hydroxyl groups bonded to the Si atom.

3. The polishing composition according to claim 1, wherein the organic silicon compound is expressed by the following general formula, (1):
X¹—(R¹—NH)ₙ—X²—Si(OR²)ₘ(R³)₃₋ₘ (1),
where X¹ indicates an amino group, methylamino group, dimethylamino group, or quaternary ammonium group; X² indicates a single bond or a divalent hydrocarbon group with a carbon number of 1 to 8; R¹ indicates a divalent hydrocarbon group with a carbon number of 1 to 8; R² indicates a hydrogen atom or a monovalent hydrocarbon group with a carbon number of 1 to 6; R³ indicates a monovalent hydrocarbon group with a carbon number of 1 to 10; n indicates an integer of 0 to 2; and m indicates 2 or 3, where the quaternary ammonium group of X¹ does not have an alkyl group with a carbon number of 2 or more.

4. The polishing composition according to claim 1, wherein the organic silicon compound is expressed by the following general formula, (2):
X³—(R⁴—NH)ₖ—X⁵—Si(OR⁶)ₕ(R⁸)₂₋ₕ—O—Si(OR⁷)ᵢ(R⁹)₂₋ᵢ—X⁶—(NH—R⁵)ⱼ—X⁴ (2),
where each of X³ and X⁴ independently indicates an amino group, methylamino group, dimethylamino group, or quaternary ammonium group; each of X⁵ and X⁶ independently indicates a single bond or a divalent hydrocarbon group with a carbon number of 1 to 8; each of R⁴ and R⁵ independently indicates a divalent hydrocarbon group with a carbon number of 1 to 8; each of R⁶ and R⁷ independently indicates a hydrogen atom or a monovalent hydrocarbon group with a carbon number of 1 to 6; each of R⁸ and R⁹ independently indicates a monvalent hydrocarbon group with a carbon number of 1 to 10; each of k and j independently indicates an integer of 0 to 2; and each of h and i independently indicates 1 or 2, wherein the quaternary ammonium group of X³ and X⁴ does not have an alkyl group with a carbon number of 2 or more.

5. The polishing composition according to claim 1, wherein the concentration of the organic silicon compound is 2 or more parts by weight, where the amount of silica is represented as 100 parts by weight.

6. The polishing composition according to claim 1, wherein the molecular weight of the organic silicon compound, M, the concentration of the organic silicon compound, c_{c}, the primary particle size of the silica, d₁, the true density of the silica, ρ₀, and the concentration of the silica, cₛ, satisfy the following expression:
(78260/M×c_{c})/{6/(d₁×ρ₀)×1000×cₛ}×100≥8.0,
where the unit for d₁ is nm, the unit for ρ₀ is g/cm³, and the unit for c_{c} and cₛ is weight %.

7. The polishing composition according to claim 1, further comprising a basic compound other than the organic silicon compound.

8. The polishing composition according to claim 7, wherein the basic compound is an inorganic compound.

9. The polishing composition according to claim 7, wherein the basic compound is an amine compound.

10. The polishing composition according to claim 1, further comprising a water-soluble polymer.
